(19) United States
(12) Patent Application Publication
(10) Pub. No.: US 2015/0064910 A1
(43) Pub. Date: Mar. 5, 2015

(54) SUBSTRATE PROCESSING METHOD, SUBSTRATE PROCESSING SYSTEM AND MEMORY MEDIUM

(71) Applicant: TOKYO ELECTRON LIMITED, Minato-ku (JP)

(72) Inventors: Miyako Kaneko, Nirasaki City (JP); Takehiko Orii, Nirasaki City (JP); Itaru Kanno, Minato-ku (JP)

(73) Assignee: TOKYO ELECTRON LIMITED, Minato-ku (JP)

(21) Appl. No.: 14/461,869

(22) Filed: Aug. 18, 2014

(30) Foreign Application Priority Data
Aug. 27, 2013 (JP) 2013-175966

(51) Int. Cl. H01L 21/02; B05B 15/12; B05B 7/00; B05B 12/14; H01L 21/306; H01L 21/67

(52) U.S. Cl. CPC H01L 21/02068; H01L 21/30604; H01L 21/67069; B05B 7/00; B05B 12/14; B05B 15/1207
USPC 438/694; 156/345.24; 156/345.1; 118/50; 118/697

(57) ABSTRACT

A substrate processing method includes supplying onto a substrate a processing liquid which contains a volatile component and forms a film, vaporizing the volatile component in the processing liquid such that the processing liquid solidifies or cures on the substrate and forms a film on the substrate, and supplying onto the film formed on the substrate a removing liquid which removes the processing liquid. The processing liquid is supplied onto the substrate after dry etching or ashing is applied to the substrate.

### CROSS-REFERENCE TO RELATED APPLICATIONS

The present application is based upon and claims the benefit of priority to Japanese Patent Application No. 2013-175966, filed Aug. 27, 2013, the entire contents of which are incorporated herein by reference.

### BACKGROUND OF THE INVENTION

1. Field of the Invention

The embodiment of the present invention relates to a substrate processing method, substrate processing system and a memory medium.

2. Description of Background Art

In a conventionally practiced process for manufacturing semiconductor devices, after dry etching or ashing is conducted on a substrate such as a semiconductor wafer, the substrate is cleaned using a chemical solution such as DHF (dilute hydrofluoric acid) for removing reaction products such as polymers remaining on the substrate (see JP 2010-027786A). The entire contents of this publication are incorporated herein by reference.

### SUMMARY OF THE INVENTION

According to one aspect of the present invention, a substrate processing method includes supplying onto a substrate a processing liquid which contains a volatile component and forms a film, vaporizing the volatile component in the processing liquid such that the processing liquid solidifies or cures on the substrate and forms a film on the substrate, and supplying onto the film formed on the substrate a removing liquid which removes the processing liquid. The processing liquid is supplied onto the substrate after dry etching or ashing is applied to the substrate.

According to another aspect of the present invention, a substrate processing system includes a processing-liquid supply device which supplies onto a substrate a processing liquid containing a volatile component for forming a film after dry etching or ashing of the substrate, and a removing-liquid supply device which supplies a removing liquid for removing the processing liquid onto a film formed on the substrate when the processing liquid solidifies or cures on the substrate through vaporization of the volatile component in the processing liquid.

### BRIEF DESCRIPTION OF THE DRAWINGS

A more complete appreciation of the invention and many of the attendant advantages thereof will be readily obtained as the same become better understood by reference to the following detailed description when considered in connection with the accompanying drawings, wherein:

FIG. 1A is a view illustrating a substrate processing method according to an embodiment of the present invention;

FIG. 1B is a view illustrating the substrate processing method according to the embodiment;

FIG. 1C is a view illustrating the substrate processing method according to the embodiment;

FIG. 2 is a view schematically showing the structure of a substrate processing system according to the embodiment;

FIG. 3 is a view schematically showing the structure of a first processing apparatus;

FIG. 4 is a view schematically showing the structure of a second processing apparatus;

FIG. 5 is a view schematically showing an example of the structure of a dry-etching device;

FIG. 6 is a view schematically showing an example of the structure of a first liquid-processing device;

FIG. 7 is a view schematically showing an example of the structure of a second liquid-processing device;

FIG. 8 is a flowchart showing the steps of processing a substrate according to the embodiment;

FIG. 9A is a view illustrating substrate processing;

FIG. 9B is a view illustrating substrate processing;

FIG. 9C is a view illustrating substrate processing; and

FIG. 9D is a view illustrating substrate processing.

### DETAILED DESCRIPTION OF THE EMBODIMENTS

The embodiments will now be described with reference to the accompanying drawings, wherein like reference numerals designate corresponding or identical elements throughout the various drawings.

### Substrate Processing Method

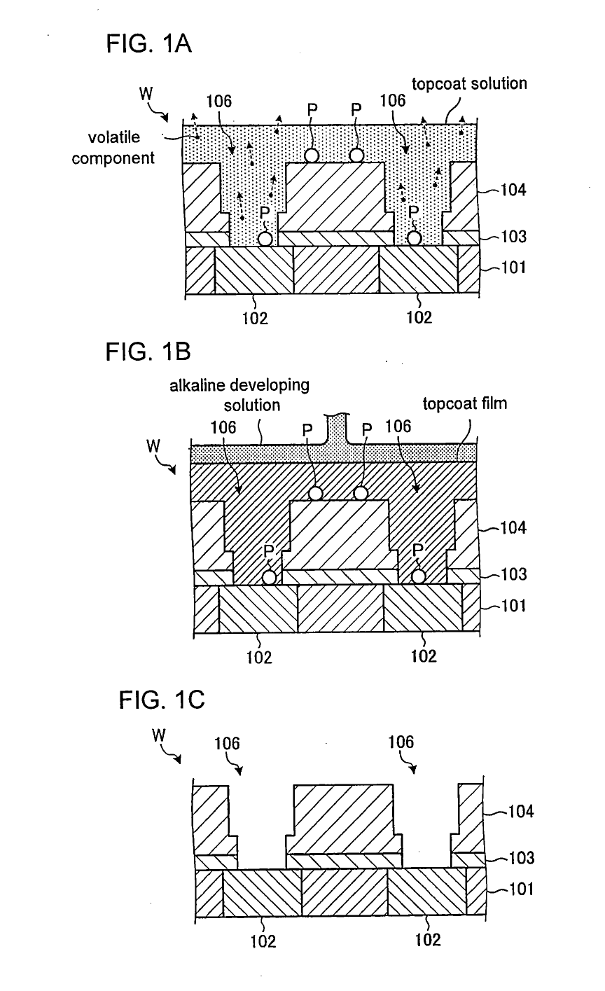

A substrate processing method according to an embodiment of the present invention is described by referring to FIG. 1A˜1C. FIG. 1A˜FIG. 1C are views illustrating a substrate processing method of the present embodiment.

In the substrate processing method of the present embodiment, a substrate such as a semiconductor wafer (hereinafter referred to as a wafer (W)) on which dry etching or ashing has been conducted is put under a process for removing reaction products such as polymers generated during the dry etching or ashing.

As shown in FIG. 1A, a wafer (W) has wiring layer 101, liner film 103 and interlayer insulation film 104, for example. They are laminated in the order of wiring layer 101, liner film 103 and interlayer insulation film 104. Cu wiring 102, an example of metal wiring, is formed in wiring layer 101.

A wafer (W) has via hole 106. Via hole 106 is formed by dry etching. Via hole 106 reaches wiring layer 101, and the surface of Cu wiring 102 is exposed at the bottom of via hole 106.

After dry etching or ashing, reaction product (P) such as a polymer generated during dry etching or ashing is attached to a wafer (W).

In the substrate processing method of the present embodiment, a processing liquid that contains a volatile component and is for forming a film on a wafer (W) (hereinafter referred to as a “film-forming processing liquid”) is supplied onto a wafer (W). More specifically, a film-forming processing liquid to form a topcoat film on a wafer (W) (hereinafter referred to as a “topcoat solution”) is supplied onto a wafer (W) in the present embodiment.

A topcoat film indicates a protective film coated on the top surface of a resist film to prevent the permeation of an immersion liquid into the resist film. An immersion liquid is used, for example, for immersion lithographic exposure in a step of immersion lithography.

A topcoat solution supplied to a wafer (W) solidifies or cures while the volatile component contained in the solution vaporizes to cause volume contraction and forms a topcoat film accordingly (see FIG. 1B). In addition, a topcoat solution contains an acrylic resin having properties that cause volume contraction when it solidifies or cures. The volume contraction of the topcoat solution is also caused when such an acrylic resin makes curing contractions. Here, “solidify” means to become a solid, and “cure” means to become a polymer through molecule bonding (crosslinking or polymerization, for example).

Then, a removing liquid for the removal of the topcoat film is supplied onto the topcoat film, as shown in FIG. 1B. In particular, an alkaline developing solution is used as a removing liquid in the present embodiment.

When an alkaline developing solution is supplied, the topcoat film peels off from the wafer (W). At that time, reaction product (P) also peels off from the wafer (W) along with the topcoat film. Accordingly, reaction product (P) is removed from the wafer (W) (see FIG. 1C).

According to the substrate processing method of the present embodiment, reaction product (P) is removed without using chemical reactions. Thus, damage to Cu wiring 102 caused by etching or the like is mitigated.

According to the substrate processing method of the present embodiment, reaction product (P) remaining on a wafer (W) after dry etching or ashing has been conducted is removed while damage to the wafer (W) is minimized. The topcoat film formed on a wafer (W) will be completely removed from the wafer (W) without performing pattern exposure.

The topcoat solution gradually solidifies or cures while making volume contraction to finally form a topcoat film. During that time, reaction product (P) remaining on a wafer (W) is also removed from the wafer (W) by the distortion (tensile force) caused by the volume contraction of the topcoat solution.

Since the volume contraction of a topcoat solution is caused by vaporization of a volatile component and curing contraction of acrylic resin, the rate of volume contraction is greater than that of a film-forming processing liquid containing only a volatile component, resulting in stronger force to remove reaction product (P). Especially, since the rate of curing contraction in acrylic resin is greater than that in other resins such as epoxy resin, using a topcoat solution is effective from the viewpoint of providing tensile force to reaction product (P).

A topcoat film swells when it is removed by an alkaline developing solution. Therefore, according to the substrate processing method of the present embodiment, reaction product (P) is removed from a wafer (W) by the strong force of volume expansion caused by the swelling of a topcoat film in addition to the volume contraction caused by the vaporization of the topcoat film.

In the present embodiment, the efficiency of removing reaction product (P) is enhanced by using a removing liquid that is alkaline.

When an alkaline developing solution is supplied, zeta potential of the same polarity is generated on the surface of a wafer (W) and the surface of reaction product (P). Reaction product (P) separated from a wafer (W) due to change in the volume of the topcoat solution is charged with zeta potential of the same polarity as that on the wafer (W), and thus reaction product (P) repels from the wafer (W). Accordingly, reaction product (P) is prevented from reattaching to the wafer (W).

After reaction product (P) is separated from a wafer (W) or the like using volume contraction of a topcoat solution, reattachment of reaction product (P) is prevented by zeta potential of the same polarity charged on the wafer (W) and reaction product (P). Thus, the efficiency of removing reaction product (P) is enhanced.

An alkaline developing solution is not limited specifically as long as it contains at least one of ammonia, tetramethylammonium hydroxide (TMAH) and a choline solution.

According to the substrate processing method of the present embodiment, it is easier to remove, for example, reaction product (P) in via hole 106, which was difficult to remove by a cleaning method using physical force.

The topcoat film formed on a wafer (W) eventually will be removed completely from the wafer (W). Thus, after the removal of the topcoat film, the wafer (W) returns to the state prior to supplying the topcoat solution, namely, a state where Cu wiring 102 is exposed.

### Structure of Substrate Processing System

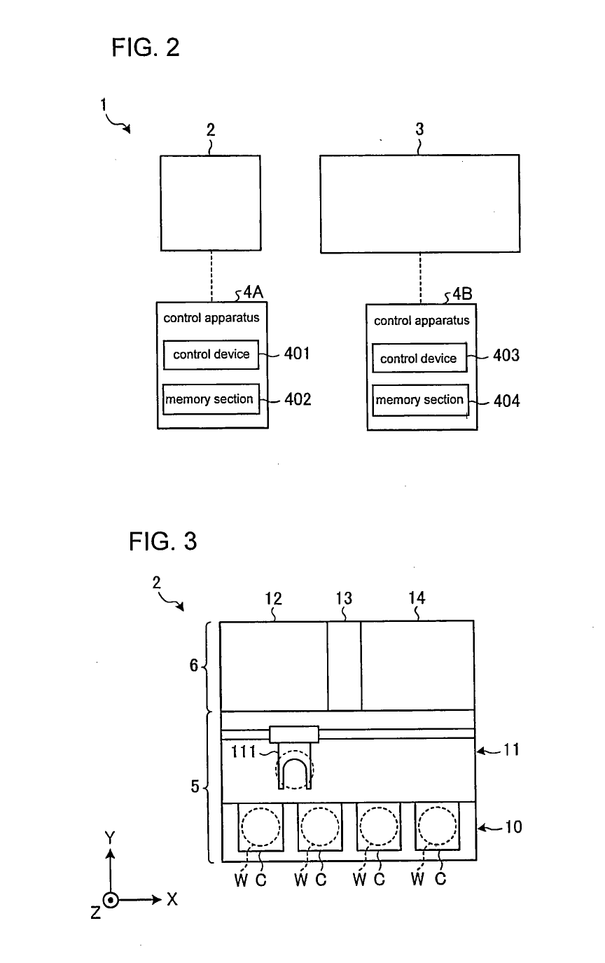

The structure of a substrate processing system that performs the aforementioned substrate processing method is described by referring to FIG. 2. FIG. 2 is a view schematically showing the structure of a substrate processing system according to the present embodiment.

As shown in FIG. 2, substrate processing system 1 of the present embodiment has first processing apparatus 2, second processing apparatus 3, first control apparatus (4A), and second control apparatus (4B).

First processing apparatus 2 performs dry etching on a wafer (W) and supplies a topcoat solution to the wafer (W). Second processing apparatus 3 supplies an alkaline developing solution to the wafer (W) processed in first processing apparatus 2.

First control apparatus (4A) is a computer, for example, and has control device 401 and memory device 402. Memory device 402 stores various programs to be executed in first processing apparatus 2. Control device 401 controls operations in first processing apparatus 2 by reading a program stored in memory device 402 and by executing it.

The same as above, second control apparatus (4B) is a computer, for example, and has control device 403 and memory device 404. Memory device 404 stores various programs to be executed in second processing apparatus 3. Control device 403 controls operations in second processing apparatus 3 by reading a program stored in memory device 404 and executing it.

The programs above may be those that are stored in a computer readable medium and installed from the memory medium to memory device 402 of first control apparatus (4A) and memory device 404 of second control apparatus (4B). Examples of a computer readable medium are hard disks (HDs), flexible discs (FDs), compact discs (CDs), magneto-optical disks (MOs), memory cards and the like.

### Structure of First Processing Apparatus

The structure of first processing apparatus 2 is described by referring to FIG. 3. FIG. 3 is a view schematically showing the structure of first processing apparatus 2. Hereinafter, to clarify positional relationships, axes (X, Y, Z) perpendicular to each other are defined, out of which a positive direction of axis (Z) is set to be a vertically upward direction.

As shown in FIG. 3, first processing apparatus 2 has loading/unloading station 5 and processing station 6. Loading/unloading station 5 and processing station 6 are set to be adjacent to each other.

Loading/unloading station 5 has carrier mounting device 10 and transfer device 11. Multiple transfer containers (hereinafter referred to as carriers (C)) to horizontally accommodate multiple wafers (W) are provided in carrier mounting device 10.

Transfer device 11 is positioned to be adjacent to carrier mounting device 10, and substrate transfer device 111 is provided therein. Substrate transfer device 111 has a wafer holding mechanism to hold a wafer (W). Also, substrate transfer device 111, which is capable of moving horizontally and vertically and of rotating around the vertical axis, transfers a wafer (W) between a carrier (C) and processing station 6 using the wafer holding mechanism.

Processing station 6 is positioned adjacent to transfer device 11. Processing station 6 has dry-etching device 12, load-lock chamber 13 and first liquid-processing device 14.

In first processing apparatus 2, substrate transfer device 111 of loading/unloading station 5 unloads a wafer (W) from a carrier (C) set in carrier mounting device 10, and loads the wafer (W) into dry-etching device 12 in processing station 6.

In dry-etching device 12, dry etching is performed on the wafer (W) loaded by substrate transfer device 111. Accordingly, via hole 106 is formed and Cu wiring 102 inside the wafer (W) is exposed (see FIG. 1A).

Dry etching is conducted under a reduced pressure. Also, in dry-etching device 12, ashing may be performed to remove unwanted resist after the dry etching.

The inner pressure in load-lock chamber 13 is set to be switchable between atmospheric pressure and a reduced pressure. A substrate transfer device (not shown) is provided in load-lock chamber 13. After the process is finished in dry-etching device 12, the wafer (W) is unloaded from dry-etching device 12 by the substrate transfer device (not shown) of load-lock chamber 13 to be loaded into first liquid-processing device 14.

More specifically, the interior of load-lock chamber 13 is kept at a reduced pressure until a wafer (W) is unloaded from dry-etching device 12, and after the completion of unloading the wafer, it is switched to atmospheric pressure by the supply of inactive gas such as nitrogen and argon. Then, after the pressure is switched to atmospheric pressure, the wafer (W) is loaded into first liquid-processing device 14 by the substrate transfer device (not shown) of load-lock chamber 13.

Since the wafer (W) is kept from outside air between unloading from dry-etching device 12 and loading into first liquid-processing device 14, oxidation of exposed Cu wiring 102 is prevented.

In first liquid-processing device 14, a film-forming processing-liquid supply process is conducted to supply a topcoat solution to the wafer (W). As described above, the topcoat solution supplied to the wafer (W) becomes a topcoat film when it solidifies or cures while making volume contraction. Accordingly, exposed Cu wiring 102 is covered by the topcoat film.

After the film-forming processing-liquid supply process, the wafer (W) is unloaded from first liquid-processing device 14 by substrate transfer device 111 and is accommodated into a carrier (C) in carrier mounting device 10. Then, the carrier (C) is transferred to second processing apparatus 3.

### Structure of Second Processing Apparatus

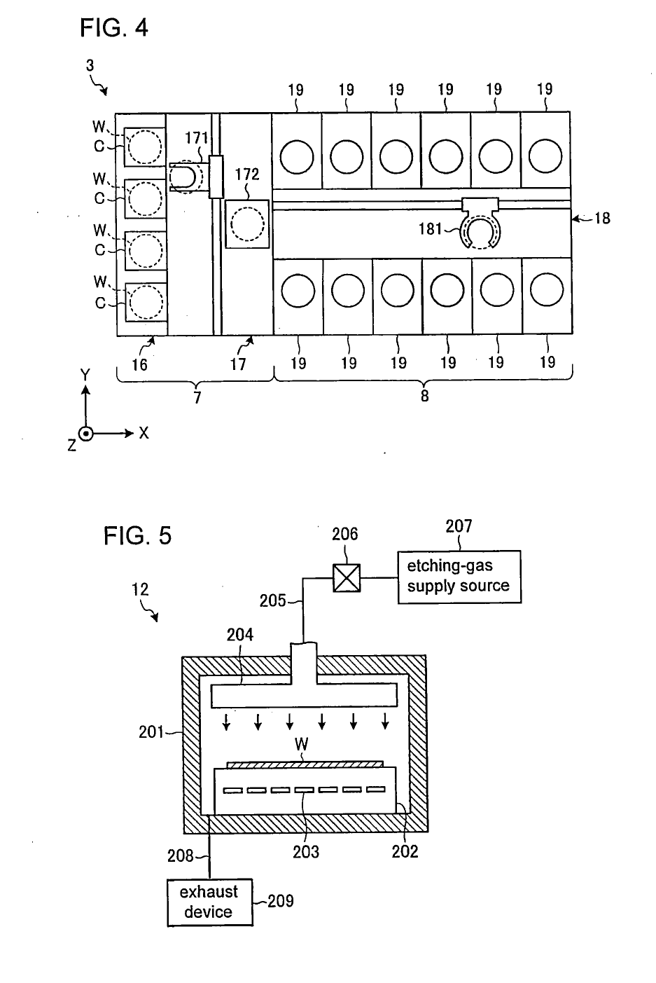

The structure of second processing apparatus 3 is described by referring to FIG. 4. FIG. 4 is a view schematically showing the structure of second processing apparatus 3.

As shown in FIG. 4, second processing apparatus 3 has loading/unloading station 7 and processing station 8. Loading/unloading station 7 and processing station 8 are set to be adjacent to each other.

Loading/unloading station 7 has carrier mounting device 16 and transfer device 17. Multiple carriers (C) are set in carrier mounting device 16.

Transfer device 17 is positioned to be adjacent to carrier mounting device 16, and substrate transfer device 171 and delivery stage 172 are provided inside. Substrate transfer device 171 has a wafer holding mechanism to hold a wafer (W). In addition, substrate transfer device 171, capable of moving horizontally and vertically and of rotating around the vertical axis, transfers a wafer (W) between a carrier (C) and delivery stage 172 using the wafer holding mechanism.

Processing station 8 is positioned adjacent to transfer device 17. Processing station 8 has transfer device 18 and multiple second liquid-processing devices 19. Multiple second liquid-processing devices 19 are arrayed along both sides of transfer device 18.

Substrate transfer device 181 is provided inside transfer device 18. Substrate transfer device 181 has a wafer holding mechanism to hold a wafer (W). In addition, substrate transfer device 181, capable of moving horizontally and vertically and of rotating around the vertical axis, transfers a wafer (W) between delivery stage 172 and a second liquid-processing device 19 using the wafer holding mechanism.

In second processing apparatus 3, substrate transfer device 171 of loading/unloading station 7 unloads from a carrier (C) a wafer (W) processed in first processing apparatus 2, and places the wafer (W) on delivery stage 172. The wafer (W) placed on delivery stage 172 is unloaded from delivery stage 172 by substrate transfer device 181 of processing station 8 and loaded into a second liquid-processing device 19.

In a second liquid-processing device 19, an alkaline developing solution is supplied to conduct a process of removing the topcoat film or the like from the wafer (W). Accordingly, reaction product (P) remaining on the wafer (W) is removed along with the topcoat film.

Next, the wafer (W) is unloaded from the second liquid-processing device 19 by substrate transfer device 181 and placed on delivery stage 172. Then, the processed wafer (W) on delivery stage 172 is returned by substrate transfer device 171 to a carrier (C) in carrier mounting device 16.

### Structure of Dry-Etching Device

The structure of dry-etching device 12 provided in first processing apparatus 2 is described by referring to FIG. 5. FIG. 5 is a view schematically showing an example of the structure of dry-etching device 12.

As shown in FIG. 5, dry-etching device 12 has sealed chamber 201 to accommodate a wafer (W), and a mounting table 202 is provided inside chamber 201 to place a wafer (W) horizontally. Mounting table 202 has temperature adjustment mechanism 203 to set a wafer (W) at a predetermined temperature by heating or cooling the wafer (W). In a side wall of chamber 201, a doorway (not shown) is provided for loading/unloading a wafer (W) to/from load-lock chamber 13.

Showerhead 204 is provided in the ceiling portion of chamber 201. Gas supply pipe 205 is connected to showerhead 204. Etching-gas supply source 207 is connected to gas supply pipe 205 via valve 206. A predetermined etching gas is supplied to showerhead 204 from etching-gas supply source 207. Showerhead 204 supplies the etching gas provided from etching-gas supply source 207 into chamber 201.

The etching gas provided from etching-gas supply source 207 is, for example, CH₃F gas, CH₂F₂ gas, CF₄ gas, O₂ gas, Ar gas or the like.

Exhaust device 209 is connected to the bottom of chamber 201 via exhaust line 208. The pressure in chamber 201 is kept at a reduced pressure by such exhaust device 209.

Dry-etching device 12 is structured as above, and dry etching is conducted on a wafer (W) positioned on mounting table 202 by supplying an etching gas from showerhead 204 into chamber 201 while the pressure in chamber 201 is kept low using exhaust device 209. Accordingly, via hole 106 is formed in the wafer (W) (see FIG. 1A) and Cu wiring 102 is exposed.

In dry-etching device 12, after dry etching is conducted on interlayer insulation film 104 (see FIG. 1A) using a resist film as a mask, for example, ashing may be conducted to remove the resist film.

### Structure of First Liquid-Processing Device

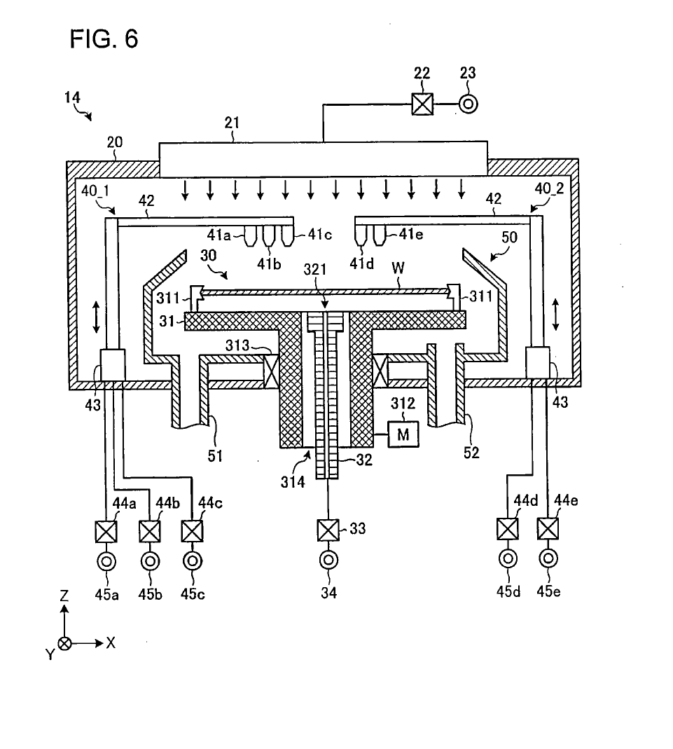

The structure of first liquid-processing device 14 is described by referring to FIG. 6. FIG. 6 is a view schematically showing an example of the structure of first liquid-processing device 14.

As shown in FIG. 6, first liquid-processing device 14 has chamber 20, substrate holding mechanism 30, liquid supply devices (40_1, 40_2) and collection cup 50.

Chamber 20 accommodates substrate holding mechanism 30, liquid supply devices (40_1, 40_2) and collection cup 50. At the ceiling portion of chamber 20, fan filter unit (FFU) 21 is provided. FFU 21 forms a downflow inside chamber 20.

Inactive-gas supply source 23 is connected to FFU 21 via valve 22. FFU 21 discharges into chamber 20 an inactive gas such as N₂ gas provided from inactive-gas supply source 23. As described, by using inactive gas as a downflow gas, oxidation of exposed Cu wiring 102 (see FIG. 1A) is prevented.

Substrate holding mechanism 30 has rotatable holding device 31 capable of holding and rotating a wafer (W), and has gas supply device 32 that is inserted into hollow portion 314 of rotatable holding device 31 for supplying a gas to the back surface of the wafer (W).

Rotatable holding device 31 is provided in substantially the center of chamber 20. Holding member 311 is formed on the top surface of rotatable holding device 31 to hold the sides of a wafer (W). A wafer (W) is horizontally held by holding member 311 so as to be slightly separated from the top surface of rotatable holding device 31.

Rotatable holding device 31 has driver mechanism 312 structured with a motor and a belt or the like to convey the rotation of the motor to rotatable holding device 31. Driver mechanism 312 rotates rotatable holding device 31 around the vertical axis. When rotatable holding device 31 rotates, a wafer (W) held by rotatable holding device 31 rotates together with rotatable holding device 31. Rotatable holding device 31 is supported by bearing 313 so as to be rotatable with respect to chamber 20 and collection cup 50.

Gas supply device 32 is a long member inserted into hollow section 314 formed in the center of rotatable holding device 31. Channel 321 is formed in gas supply device 32, and is connected to N₂ gas supply source 34 via valve 33. Gas supply device 32 supplies N₂ gas provided from N₂ gas supply source 34 to the back surface of a wafer (W) via valve 33 and channel 321.

N₂ gas supplied through valve 33 is a high-temperature N₂ gas (approximately 90° C., for example), and is used for the later-described vaporization acceleration process.

When substrate holding mechanism 30 receives a wafer (W) from the substrate transfer device (not shown) of load-lock chamber 13, substrate holding mechanism 30 lifts gas supply device 32 using an elevator mechanism (not shown) and then mounts the wafer (W) on support pins (not shown) provided on the top surface of gas supply device 32. Then, substrate holding mechanism 30 lowers gas supply device 32 to a predetermined position and delivers the wafer (W) to holding member 311 of rotatable holding device 31. In addition, when substrate holding mechanism 30 delivers a processed wafer (W) to substrate transfer device 111, substrate holding mechanism 30 lifts gas supply device 32 using the elevator mechanism (not shown) and then mounts the wafer (W) held by holding member 311 onto the support pins (not shown). Then, substrate holding mechanism 30 delivers the wafer (W) mounted on the support pins (not shown) to substrate transfer device 111.

Liquid supply device (40_1) has nozzles (41a˜41c) and arm 42 to horizontally support nozzles (41a˜41c), and swivel elevator mechanism 43 which swivels, lifts and lowers arm 42.

Liquid supply device (40_1) supplies to a wafer (W) a predetermined chemical solution (DHF, here) from nozzle (41a), DIW (pure water) as the rinse solution from nozzle (41b), and IPA (isopropyl alcohol) as the drying solvent from nozzle (41c).

More specifically, DHF supply source (45a) is connected to nozzle (41a) via valve (44a), DIW supply source (45b) is connected to nozzle (41b) via valve (44b), and IPA supply source (45c) is connected to nozzle (41c) via valve (44c). Here, the DHF supplied from nozzle (41a) is a dilute hydrofluoric acid which is diluted to a certain concentration so as not to corrode Cu wiring 102.

Liquid supply device (40_2) has nozzles (41d, 41e), arm 42 to horizontally support nozzles (41d, 41e), and swivel elevator mechanism 43 which swivels, lifts and lowers arm 42.

To wafer (W), liquid supply device (40_2) supplies from nozzle (41d) MIBC (4-methyl-2-pentanole) as a solvent having affinity with a topcoat solution, and supplies the topcoat solution from nozzle (41e).

More specifically, MIBC supply source (45d) is connected to nozzle (41d) via valve (44d), and topcoat supply source (45e) is connected to nozzle (41e) via valve (44e).

MIBC is also contained in the topcoat solution and has affinity with the topcoat solution. Instead of MIBC, it is an option to use, for example, PGME (propylene glycol monomethyl ether), PGMEA (propylene glycol monomethyl ether acetate) or the like as a solvent having affinity with a topcoat solution.

Here, nozzles (41a˜41e) are each set exclusively for one processing liquid, but multiple processing liquids may share a nozzle. However, if a nozzle is shared, when processing liquids are not preferred to be mixed, for example, a draining step is required to drain the liquid remaining in the nozzle or the pipe, resulting in a waste of the liquid. By contrast, if nozzles (41a˜41e) are each dedicated to one processing liquid, a draining step is not necessary to drain a processing liquid, thus the processing liquid is not wasted.

Collection cup 50 is positioned to surround rotatable holding device 31, and collects the processing liquid that scatters from a wafer (W) when rotatable holding device 31 rotates. At the bottom of collection cup 50, drain port 51 is formed, and the processing liquid collected in collection cup 50 is drained to the outside of first liquid processing device 14 through drain port 51. In addition, at the bottom of collection cup 50, exhaust port 52 is formed to exhaust N₂ gas supplied by gas supply device 32, as well as the inactive gas supplied from FFU 21, to the outside of first liquid-processing device 14.

### Structure of Second Liquid-Processing Device

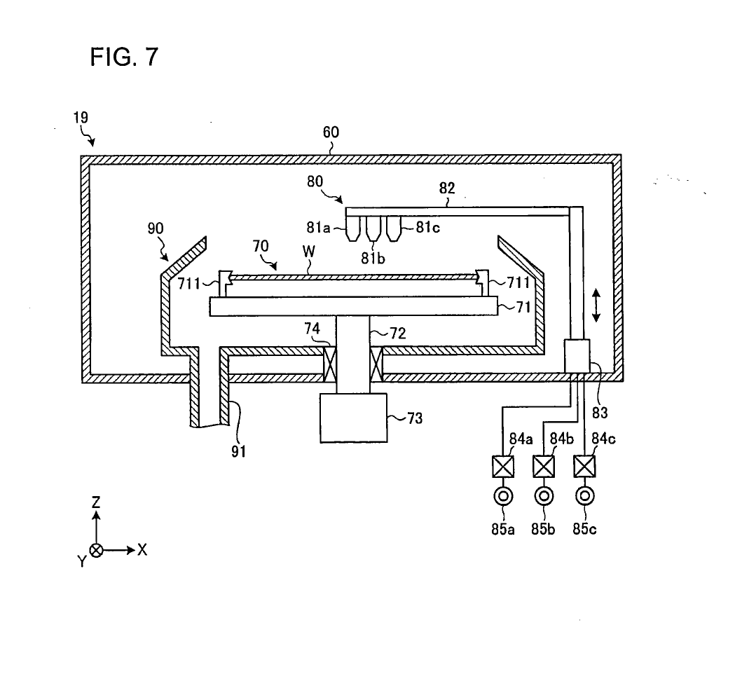

The structure of second liquid-processing device 19 provided in second processing apparatus 3 is described by referring to FIG. 7. FIG. 7 is a view schematically showing an example of the structure of second liquid-processing device 19.

As shown in FIG. 7, second liquid-processing device 19 has substrate holding mechanism 70, liquid supply device 80 and collection cup 90 in chamber 60.

Substrate holding mechanism 70 has rotatable holding device 71, support member 72 and driver member 73. Rotatable holding device 71 is provided in substantially the center of chamber 60. Holding member 711 to hold sides of a wafer (W) is provided on the top surface of rotatable holding device 71. A wafer (W) is held horizontally by holding member 711 to be slightly separated from the top surface of rotatable holding device 71. Support member 72 extends vertically. Its base portion is supported by driver member 73 to be rotatable and its tip portion horizontally supports rotatable holding device 71. Driver member 73 rotates support member 72 around the vertical axis.

By rotating support member 72 using driver member 73, substrate holding mechanism 70 rotates rotatable holding device 71 supported by support member 72, and thereby rotates a wafer (W) held by rotatable holding device 71.

Liquid supply device 80 has nozzles (81a˜81c), arm 82 to horizontally support nozzles (81a˜81c), and swivel elevator mechanism 83 to swivel, lift and lower arm 82.

To a wafer (W), liquid supply device 80 supplies from nozzle (81a) DHF as a predetermined chemical solution, supplies from nozzle (81b) an alkaline developing solution as a removing liquid to remove a topcoat film, and supplies from nozzle (81c) DIW as a rinse solution.

In particular, DHF supply source (85a) is connected to nozzle (81a) via valve (84a), alkaline developing solution supply source (85b) is connected to nozzle (81b) via valve (84b), and DIW supply source (85c) is connected to nozzle (81c) via valve (84c).

The alkaline developing solution supplied from nozzle (81b) contains an anticorrosion agent to prevent corrosion of Cu wiring 102. Accordingly, in the later-described removing-liquid supply process, the topcoat film is removed and damage to Cu wiring 102 is suppressed. In addition, the DHF supplied from nozzle (81a) is diluted to a certain concentration so as not to corrode Cu wiring 102.

Collection cup 90 is positioned to surround rotatable holding device 71 so that the processing liquid is prevented from scattering to surrounding portions. At the bottom of collection cup 90, drain port 91 is formed and the processing liquid collected in collection cup 90 is drained through drain port 91 to the outside of second liquid-processing device 19.

### Specific Operations of Substrate Processing System

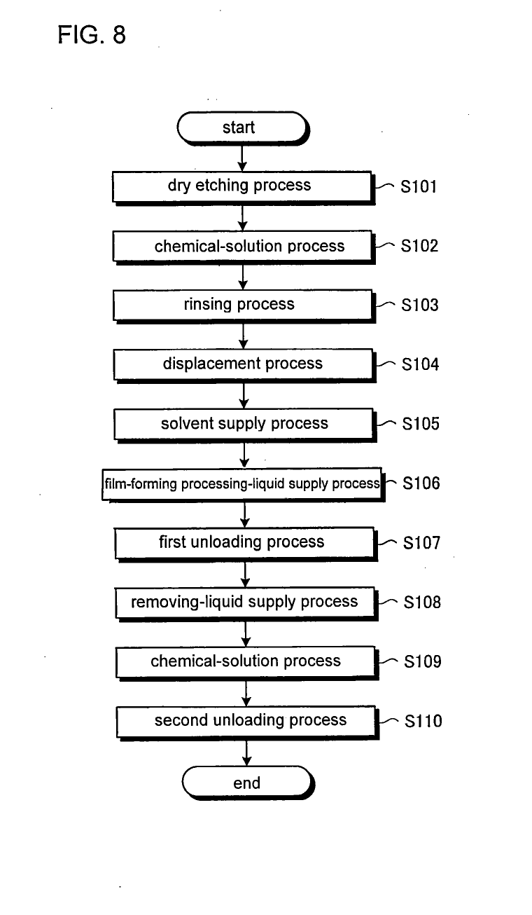

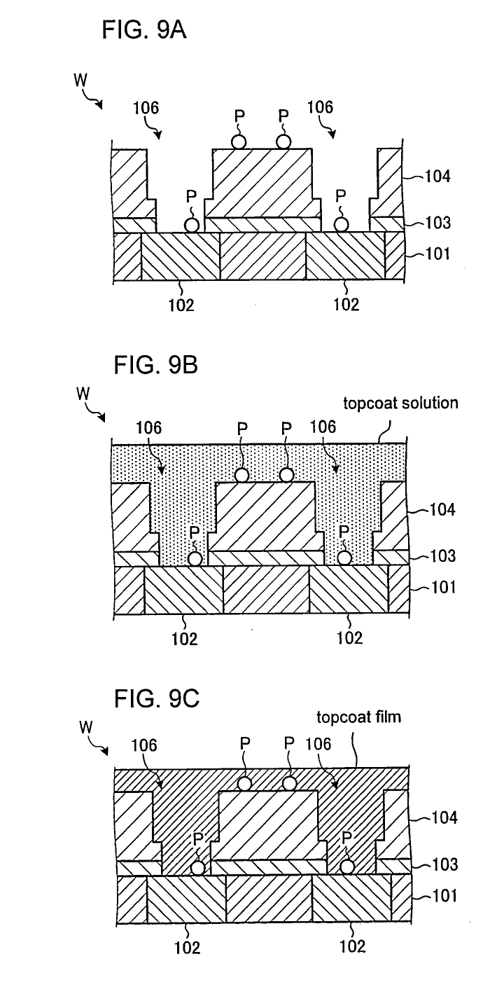

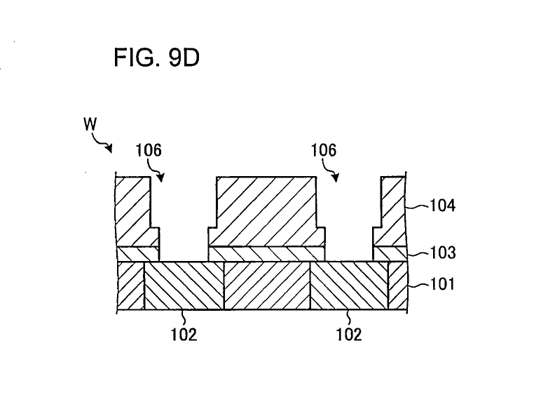

Specific operations of substrate processing system 1 are described by referring to FIG. 8 and FIG. 9A˜9D. FIG. 8 is a flowchart showing processing steps of substrate processing according to an embodiment of the present invention. FIG. 9A˜9D are views illustrating substrate processing.

FIG. 9A is a view illustrating a dry-etching process in FIG. 8 (step S101),

FIG. 9B is a view illustrating a film-forming processing-liquid supply process in FIG. 8 (step S106), FIG. 9C is a view showing a wafer (W) after the film-forming processing-liquid supply process in FIG. 8 (step S106), and FIG. 9D is a view showing a wafer (W) after a removing-liquid supply process in FIG. 8 (step S108). Each step in FIG. 8 is conducted according to controls from first control apparatus (4A) or second control apparatus (4B).

In substrate processing system 1 of the present embodiment, a dry-etching process (step S101) through a first unloading process (step S107) shown in FIG. 8 are conducted in first processing apparatus 2, whereas a removing-liquid supply process (step S108) through second unloading process (step S110) are conducted in second processing apparatus 3.

First, a dry-etching process is conducted in dry-etching device 12 (step S101) as shown in FIG. 8. In a dry-etching process, dry etching or ashing is conducted on a wafer (W) in dry-etching device 12. Accordingly, Cu wiring 102 formed in the wafer (W) is exposed (see FIG. 9A).

The wafer (W) is loaded into first liquid-processing device 14. Since such loading process is conducted in load-lock chamber 13, oxidation of exposed Cu wiring 102 is prevented.

A chemical-solution process is conducted in first liquid-processing device 14 (step S102). In the chemical-solution process, nozzle (41a) of liquid supply device (40_1) (see FIG. 6) is positioned over the center of the wafer (W). Then, DHF is supplied to the wafer (W) from nozzle (41a). The DHF supplied to the wafer (W) spreads over the surface of wafer (W) by centrifugal force generated as the wafer (W) rotates.

Accordingly, surfaces of Cu wiring 102 and reaction product (P) are slightly dissolved by DHF, and the adhesive strength of reaction product (P) is thereby lowered. Thus, reaction product (P) is easier to remove now.

Here, the chemical solution treatment in step (S102) is conducted for the purpose of making the removal of reaction product (P) easier, and is thus conducted under etching conditions set at a low level so as not to remove reaction product (P) completely. Low etching conditions are, for example, a duration shorter than that required for completely removing reaction product (P), or a DHF concentration lower than that required for completely removing reaction product (P).

Accordingly, compared with a case when reaction product (P) is removed using only DHF as conventionally practiced, reaction product (P) is removed more effectively while damage to Cu wiring 102 is suppressed. In addition, since the DHF supplied from nozzle (41a) in the present embodiment is diluted to a concentration that will not corrode Cu wiring 102, damage to Cu wiring 102 is even more certainly suppressed.

In a chemical-solution process, reaction product (P) with a relatively smaller particle diameter tends to be removed, whereas in a process of removing reaction product (P) using a later-described topcoat solution and an alkaline removing solution, reaction product (P) with a relatively large particle diameter tends to be removed. Thus, by combining those processes, reaction product (P) is removed more effectively.

The chemical solution supplied from nozzle (41 a) is not limited to DHF, and it may be a solution containing, for example, ammonium fluoride, hydrochloric acid, sulfuric acid, hydrogen peroxide, phosphoric acid, acetic acid, nitric acid, ammonium hydroxide, organic acid or ammonium fluoride.

In first liquid-processing device 14, a rinsing process is employed to rinse the surface of a wafer (W) using DIW (step S103). In the rinsing process, nozzle (41b) (see FIG. 6) is positioned over the center of a wafer (W). Then, valve (44b) is opened for a certain duration and DIW is supplied from nozzle (41b) to the surface of the rotating wafer (W). Accordingly, DHF remaining on the wafer (W) is rinsed off.

In first liquid-processing device 14, a displacement process is conducted (step S104). In a displacement process, nozzle (41c) (see FIG. 6) is positioned over the center of a wafer (W). Next, valve (44c) is opened for a certain duration to supply IPA from nozzle (41c) to the surface of the rotating wafer (W), and the DIW on the wafer (W) is displaced by IPA. Then, the rotation of the wafer (W) is turned off while IPA remains on the wafer (W). When the displacement process is finished, liquid supply device (40_1) moves to a position off the wafer (W). Here, steps (S102)˜(S104) are not always required to be conducted.

First liquid-processing device 14 conducts a solvent supply process (step S105). A solvent supply process is for supplying to a wafer (W) MIBC that has affinity with a topcoat solution prior to supplying the topcoat solution as a film-forming processing liquid.

In particular, nozzle (41d) of liquid supply device (40_2) is positioned over the center of a wafer (W), and then MIBC is supplied to the wafer (W) from nozzle (41d). The MIBC supplied to the wafer (W) spreads onto the surface of wafer (W) by centrifugal force generated as the wafer (W) rotates.

By spreading MIBC having affinity with a topcoat solution on a wafer (W) in advance, it is easier to spread the topcoat solution on the wafer (W) and to fill via hole 106 (see FIG. 9A) in the later film-forming processing-liquid supply process. Thus, the consumption amount of the topcoat solution is lowered while reaction product (P) in via hole 106 is removed more certainly.

MIBC has affinity with a topcoat solution, but hardly mixes with DIW and shows low affinity with it. For that matter, prior to supplying MIBC, DIW is displaced by IPA, which has higher affinity with MIBC than with DIW in first liquid-processing device 14. Accordingly, compared with a case where a solvent supply process (step S105) is conducted directly after a rinsing process (step S103), MIBC tends to be spread over the surface of wafer (W), and thus the consumption amount of MIBC is reduced.

If a solvent having affinity with a film-forming processing liquid also has affinity with DIW, a displacement process in step (S104) may be omitted.

When a topcoat film is preferred to be spread effectively on the front surface of a wafer (W) in a short period of time, the aforementioned solvent supply process is preferred to be conducted. If a film-forming processing liquid has affinity with IPA, the solvent supply process in step (S105) may be omitted.

In first liquid-processing device 14, a film-forming processing-liquid supply process is conducted (step S106). In the film-forming processing-liquid supply process, nozzle (41e) of liquid supply device (40_2) is positioned over the center of a wafer (W). Then, as shown in FIG. 9B, a topcoat solution as the film-forming processing liquid is supplied from nozzle (41e) to the surface of the wafer (W) where circuits are formed without a resist film formed thereon.

The topcoat solution supplied to the wafer (W) spreads over the surface of wafer (W) by centrifugal force generated as the wafer (W) rotates. Accordingly, as shown in FIG. 9B, a liquid film of the topcoat solution is formed on the entire surface of the wafer (W). At that time, the wettability on the surface of the wafer (W) is high because of the MIBC supplied on the wafer (W) earlier in step (S105). Thus, it is easier to spread the topcoat solution over the surface of wafer (W) and to fill via hole 106. Accordingly, the consumption amount of the topcoat solution is reduced and the processing time is shortened.

When the wafer (W) rotates, the volatile component vaporizes, and the topcoat solution solidifies or cures. Accordingly, a topcoat film is formed on the entire surface of the wafer (W) (see FIG. 9C).

In first liquid-processing device 14, a vaporization acceleration process is performed. The vaporization acceleration process is to accelerate further vaporization of a volatile component contained in the topcoat solution for forming a film on the entire surface of a wafer (W). In particular, valve 33 (see FIG. 6) is opened for a certain duration to supply a high-temperature N₂ gas from gas supply device 32 to the back surface of a rotating wafer (W). Accordingly, the topcoat solution is heated along with the wafer (W), and vaporization of its volatile component is facilitated.

The vaporization acceleration process may be conducted by reducing the pressure in chamber 20 using a vacuum device (not shown), or by reducing the humidity in chamber 20 using a gas supplied from FFU 21. Vaporization of a volatile component is also accelerated by either of those processes.

Here, an example was shown where a vaporization acceleration process is conducted in first liquid-processing device 14. However, the vaporization acceleration process may be omitted. Namely, it is an option to keep the wafer (W) in first liquid-processing device 14 until the topcoat solution naturally solidifies or cures. Alternatively, vaporization of the topcoat solution may be accelerated by turning off the rotation of the wafer (W) or by rotating the wafer (W) at a rotation rate that prevents the topcoat solution from being shaken off and exposing the surface of wafer (W).

A first unloading process is conducted in first liquid-processing device 14 (step S107). During the first unloading process, substrate transfer device 111 unloads a wafer (W) from first liquid-processing device 14, transfers the wafer to carrier mounting device 10, and accommodates the wafer into a carrier (C) positioned in carrier mounting device 10.

During that time, exposed Cu wiring 102 in the wafer (W) is covered by the topcoat film (see FIG. 9C). Namely, since Cu wiring 102 is sealed from the outside air, it will not be subject to adverse effects such as oxidation or the like.

The wafer (W) accommodated in a carrier (C) is transferred from first processing apparatus 2 to carrier mounting device 16 in second processing apparatus 3. Then, the wafer (W) is unloaded from the carrier (C) by substrate transfer device 171 of second processing apparatus 3 (see FIG. 4), and is loaded into second liquid-processing device 19 by way of delivery stage 172 and substrate transfer device 181.

In second liquid-processing device 19, a removing-liquid supply process is conducted first (step S108). In the removing-liquid supply process, nozzle (81b) (see FIG. 7) is positioned over the center of a wafer (W). Then, valve (84b) is opened for a certain duration, and an alkaline developing solution as a removing liquid is supplied onto a rotating wafer (W) from nozzle (81b). Accordingly, the topcoat film formed on the wafer (W) peels off and dissolves so as to be removed from the wafer (W).

During that time, reaction product (P) remaining on the wafer (W) peels off the wafer (W) and is removed (see FIG. 9D).

In the above, since the wafer (W) and reaction product (P) are charged with zeta potential of the same polarity, the wafer (W) and reaction product (P) repel each other and reaction product (P) is prevented from reattaching to the wafer (W) or the like.

The alkaline developing solution contains an anticorrosion agent to prevent corrosion of Cu wiring 102. Thus, even if the alkaline developing solution is attached to Cu wiring 102, corrosion of Cu wiring 102 is suppressed. Thus, according to substrate processing system 1 of the present embodiment, the topcoat film is removed while damage to Cu wiring 102 is suppressed.

A chemical-solution process is conducted in second liquid-processing device 19 (step S109). In the chemical-solution process, nozzle (81a) (see FIG. 7) is positioned over the center of a wafer (W). Then, DHF is supplied to the wafer (W) from nozzle (81a). The DHF supplied to the wafer (W) is spread over the surface of wafer (W) by centrifugal force generated as the wafer (W) rotates.

By performing a chemical solution supply process after the removing-liquid supply process, namely, after the topcoat film has been removed, reaction product (P) that was not completely removed when the topcoat film peeled off (especially, reaction product (P) with a smaller particle diameter) can be removed at this time. In such a case as well, compared with generally practiced chemical-solution cleaning processes, reaction product (P) is removed even more effectively and corrosion of a wafer (W) is suppressed.

After the chemical-solution process is finished, a rinsing process is performed in second liquid-processing device 19 by supplying DIW from nozzle (81c) to rinse the surface of the wafer (W). Accordingly, dissolved topcoat film and reaction product (P) floating in the alkaline developing solution are rinsed off the wafer (W) with DIW. In addition, when the rinsing process is finished, a drying process is conducted in second liquid-processing device 19 by increasing the rotation rate of the wafer (W) for a certain duration so as to dry the wafer (W) by shaking off the remaining DIW from the surface of the wafer (W). Then, the rotation of the wafer (W) is stopped.

A second unloading process is conducted in second liquid-processing device 19 (step S110). In the second unloading process, the wafer (W) is unloaded by substrate transfer device 181 (see FIG. 4) from second liquid-processing device 19, and is accommodated in a carrier (C) positioned in carrier mounting device 16 by way of delivery device 172 and substrate transfer device 171. When the second unloading process is finished, a series of substrate processes on a wafer (W) is completed.

As described so far, substrate processing system 1 of the present embodiment has liquid supply device (40_2) (an example of processing-liquid supply device) and liquid supply device 80 (an example of removing-liquid supply device). After dry etching or ashing, liquid supply device (40_2) supplies to a wafer (W) a topcoat solution, which is a processing liquid containing a volatile component and is for forming a film on a substrate. In addition, liquid supply device 80 supplies an alkaline developing solution, which is a removing liquid to remove the entire topcoat solution after the topcoat solution has solidified or cured on the wafer (W) through vaporization of the volatile component.

According to substrate processing system 1 of the present embodiment, reaction product (P) that remains on the substrate after dry etching or ashing has been conducted is removed while damage to the substrate is suppressed.

The above embodiment describes an example using a topcoat solution as the film-forming processing liquid. However, the film-forming processing liquid is not limited to a topcoat solution.

For example, film-forming processing liquid may be such that contains phenolic resin. Phenolic resin also contracts when cured, the same as acrylic resin described above. Thus, such a processing liquid is also effective as a topcoat solution since tensile force is exerted on reaction product (P).

An example of the film-forming processing liquid that contains phenolic resin is a resist solution. A resist solution is a film-forming processing liquid to form a resist film on a wafer (W). In particular, a novolac phenol resin is contained in a resist solution.

When a resist solution is used as the film-forming processing liquid, a thinner capable of dissolving the resist solution may be used as the removing liquid. When a thinner is used as the removing liquid, a rinsing process may be omitted after the removing-liquid supply process. In addition, when a resist solution is used as the film-forming processing liquid, it is an option to supply the removing liquid after exposure treatment such as entire-image exposure and the like is conducted on the resist film formed on the wafer (W). In such a case, the removing liquid may be a developing solution or a thinner.

A synthetic resin contained in a film-forming processing liquid is not limited to acrylic resin or phenolic resin mentioned above as long as it contracts when cured. Examples of a synthetic resin contained in a film-forming processing liquid are epoxy resins, melamine resins, urea resins, unsaturated polyester resins, alkyd resins, polyurethane, polyimide, polyethylene, polypropylene, polyvinyl chloride, polystyrene, polyvinyl acetate, polytetrafluoroethylene, acrylonitrile butadiene styrene resins, acrylonitrile styrene resins, polyamide, nylon, polyacetal, polycarbonate, modified polyphenylene ether, polybutylene terephthalate, polyethylene terephthalate, polyphenylene sulfide, polysulfone, polyether ether ketone, polyamide-imide and the like.

An antireflection film-forming liquid may be used as the film-forming processing liquid. An antireflection film-forming liquid is for forming an antireflection film on a wafer (W). An antireflection film is a protective film to decrease surface reflection of a wafer (W) and to increase its transmittability. When such an antireflection film-forming liquid is used as the film-forming processing liquid, DIW capable of dissolving the antireflection film-forming liquid may be used as the removing liquid.

In addition to the volatile component and a synthetic resin, the film-forming processing liquid may contain a predetermined chemical solution that dissolves a wafer (W), material formed on the wafer (W) or contaminants attached to the wafer (W). “Material formed on the wafer (W)” means Cu wiring 102, for example, and “contaminants attached to the wafer (W)” means reaction product (P), for example. In addition, examples of a “predetermined chemical solution” are solutions that contain hydrogen fluoride, ammonium fluoride, hydrochloric acid, sulfuric acid, hydrogen peroxide, phosphoric acid, acetic acid, nitric acid, ammonium hydroxide, organic acid or ammonium fluoride. Since the adhesive strength of reaction product (P) is weakened when the surface of reaction product (P) is dissolved by such a chemical solution, reaction product (P) becomes easier to remove.

A “predetermined chemical solution” is used under low etching conditions compared with a chemical solution used in a generally practiced chemical-solution cleaning process conducted only through chemical reactions of the chemical solution. Thus, compared with a generally practiced chemical-solution cleaning process, reaction product (P) is removed more effectively while corrosion of the wafer (W) is suppressed.

The above embodiment describes an example using an alkaline developing solution as the removing liquid. However, the removing liquid may be such that is prepared by adding hydrogen peroxide to the alkaline developing solution. By adding hydrogen peroxide to an alkaline developing solution, surface roughness of a wafer (W) caused by the alkaline developing solution is suppressed.

The removing liquid may be an organic solvent such as thinner, toluene, acetates, alcohols and glycols (propylene glycol monomethyl ethers) or acidic developing solutions containing acetic acid, formic acid, hydroxyacetic acid or the like.

In addition, the removing liquid may further contain a surfactant. Since a surfactant works to weaken surface tension, it is capable of suppressing reaction product (P) from reattaching to the wafer (W).

The above embodiment describes an example where metal wiring formed in a wafer (W) is Cu wiring 102. However, the metal wiring is not limited to Cu wiring 102, and any other metal wiring may be formed. The removing liquid for the topcoat film may be selected from those containing an anticorrosion agent suitable for that type of metal wiring.

The above embodiment describes an example where the target material of dry etching is metal wiring. However, the target material or the target structure of dry etching is not limited to metal wiring. Also, the substrate processing method of the present embodiment may apply for removing reaction products after the resist is removed by ashing. For example, the substrate processing method is effective for cleaning a wafer after ion injection has been conducted using a resist pattern as a mask and after the resist has been removed by ashing.

The above embodiment describes an example where a chemical-solution process is conducted before the film-forming processing-liquid supply process and after the removing-liquid supply process. However, the chemical-solution process may be conducted either before the film-forming processing-liquid supply process or after the removing-liquid supply process. Alternatively, it is an option not to conduct a chemical-solution process.

If a chemical-solution process is conducted after the removing-liquid supply process, liquid supply device (40_2) in first liquid-processing device 14 may be provided in second liquid-processing device 19, or another processing device for chemical solution cleaning may be provided separately.

The structure of substrate processing system 1 is not limited to the example shown in the above embodiment.

For example, the above embodiment shows an example where dry-etching device 12 and first liquid-processing device 14 are provided in first processing apparatus 2. However, part of or the entire dry-etching device 12 and first liquid-processing device 14 may be provided independently as a separate device.

Dry-etching device 12, load-lock chamber 13 and first liquid-processing device 14 provided in first processing apparatus 2 may be arranged in processing station 8 of second processing apparatus 3. In such a structure, first processing apparatus 2 is omitted.

In the above embodiment, a chemical-solution process (step (S102) of FIG. 8) is set to be conducted in first liquid-processing device 14. However, such a chemical-solution process may be conducted in another processing device different from first liquid-processing device 14. In the same manner, a chemical-solution process (step (S109) of FIG. 8) is set to be conducted in second liquid-processing device 19, but such a chemical-solution process may be conducted in another processing device different from second liquid-processing device 19.

In the above embodiment, a film-forming processing-liquid supply process and a removing-liquid supply process are conducted by separate devices (first liquid-processing device 14 and second liquid-processing device 19), but a film-forming processing-liquid supply process and a removing-liquid supply process may be conducted using one device (a first liquid-processing device 14, for example). Alternatively, a chemical-solution process, a film-forming processing-liquid supply process and a removing-liquid supply process may be conducted in first liquid-processing device 14, for example.

When metal wiring in the substrate is exposed, the exposed metal wiring may be damaged by a chemical solution.

However, using a substrate processing method, a substrate processing system and a memory medium according to embodiments of the present invention, reaction products remaining on a substrate after dry etching or ashing has been conducted are removed while damage to the substrate is suppressed.

A substrate processing method according to an embodiment of the present invention includes a processing-liquid supply process and a removing-liquid supply process. In the processing-liquid supply process, a processing liquid that contains a volatile component and is for forming a film on a substrate is supplied to a substrate after dry etching or ashing. In the removing-liquid supply process, a removing liquid is supplied to the processing liquid that has solidified or cured on the substrate through vaporization of the volatile component so that the processing liquid is removed.

According to an embodiment of the present invention, reaction products remaining on a substrate after dry etching or ashing has been conducted are removed while damage to the substrate is suppressed.

Obviously, numerous modifications and variations of the present invention are possible in light of the above teachings. It is therefore to be understood that within the scope of the appended claims, the invention may be practiced otherwise than as specifically described herein.

What is claimed is:

1. A substrate processing method, comprising:
supplying onto a substrate a processing liquid which includes a volatile component and forms a film;
vaporizing the volatile component in the processing liquid such that the processing liquid solidifies or cures on the substrate and forms a film on the substrate; and
supplying onto the film formed on the substrate a removing liquid which removes the processing liquid,
wherein the processing liquid is supplied onto the substrate after dry etching or ashing is applied to the substrate.

2. A substrate processing method according to claim 1, wherein the substrate which received the dry etching or ashing has a metal wiring formed inside the substrate and having at least one exposed portion exposed from the substrate, and the removing liquid includes an anticorrosion agent for the metal wiring.

3. A substrate processing method according to claim 1, further comprising:
supplying onto the substrate a chemical solution which dissolves material formed on the substrate or contaminant attached to the substrate after the dry etching or ashing is applied to the substrate,
wherein the chemical solution is supplied to the substrate before the supplying of the processing liquid.

4. A substrate processing method according to claim 2, further comprising:
supplying onto the substrate a chemical solution which dissolves material formed on the substrate or contaminant attached to the substrate after the dry etching or ashing is applied to the substrate,
wherein the chemical solution is supplied to the substrate before the supplying of the processing liquid.

5. A substrate processing method according to claim 1, further comprising:
supplying onto the substrate a chemical solution which dissolves material formed on the substrate or contaminant attached to the substrate after the supplying of the removing liquid.

6. A substrate processing method according to claim 2, further comprising:
supplying onto the substrate a chemical solution which dissolves material formed on the substrate or contaminant attached to the substrate after the supplying of the removing liquid.

7. A substrate processing method according to claim 1, wherein the substrate which received the dry etching or ashing has a metal wiring formed inside the substrate and having at least one exposed portion exposed from the substrate, and the film formed by solidifying or curing the processing liquid is formed such that the film covers the exposed portion of the metal wiring.

8. A substrate processing method according to claim 7, further comprising:
supplying onto the substrate a chemical solution which dissolves material formed on the substrate or contaminant attached to the substrate after the dry etching or ashing is applied to the substrate,
wherein the chemical solution is supplied to the substrate before the supplying of the processing liquid.

9. A substrate processing method according to claim 7, further comprising:
supplying onto the substrate a chemical solution which dissolves material formed on the substrate or contaminant attached to the substrate after the supplying of the removing liquid.

10. A substrate processing method according to claim 1, wherein the processing liquid is a topcoat solution, and the removing liquid is an alkaline developing solution.

11. A substrate processing system, comprising:
a processing-liquid supply device configured to supply onto a substrate a processing liquid which includes a volatile component and forms a film after dry etching or ashing of the substrate; and
a removing-liquid supply device configured to supply a removing liquid which removes the processing liquid onto a film formed on the substrate when the processing liquid solidifies or cures on the substrate through vaporization of the volatile component in the processing liquid.

12. A substrate processing system according to claim 11, further comprising:
a dry etching device configured to apply an etching gas to the substrate.

13. A substrate processing system according to claim 11, wherein the processing-liquid supply device is positioned in a first processing apparatus, and the removing-liquid supply device is positioned in a second processing apparatus.

14. A substrate processing system according to claim 13, wherein the first processing apparatus includes a dry etching device configured to apply an etching gas to the substrate.

15. A substrate processing system according to claim 11, wherein the processing liquid is a topcoat solution, and the removing liquid is an alkaline developing solution.

16. A substrate processing system according to claim 11, further comprising:
a chemical-solution supply device configured to supply to the substrate a chemical solution which dissolves material formed on the substrate or contaminant attached to the substrate after the after the dry etching or ashing of the substrate; and
a control device configured to control supply of the processing liquid by the processing-liquid supply device and supply of the chemical solution by the chemical-solution supply device,
wherein the control device controls the chemical-solution supply device such that the chemical solution is supplied to the substrate before the supply of the processing liquid by the processing-liquid supply device.

17. A substrate processing system according to claim 11, further comprising:
a chemical-solution supply device configured to supply to the substrate a chemical solution which dissolves material formed on the substrate or contaminant attached to the substrate after the after the dry etching or ashing of the substrate; and
a control device configured to control supply of the removing liquid by the removing-liquid supply device and supply of the chemical solution by the chemical-solution supply device,
wherein the control device controls the chemical-solution supply device such that the chemical solution is supplied to the substrate after the supply of the removing liquid by the removing-liquid supply device.

18. A substrate processing system according to claim 11, wherein the processing-liquid supply device is positioned in a first processing apparatus, the removing-liquid supply device is positioned in a second processing apparatus, the first processing apparatus includes a first control device configured to control supply of the processing liquid by the processing-liquid supply device, and the second processing apparatus includes a second control device configured to control supply of the removing liquid by the removing-liquid supply device.

19. A substrate processing system according to claim 13, further comprising:
a transfer device configured to transfer the substrate from the first processing apparatus to the second processing apparatus.

20. A non-transitory computer readable medium including a program, which when executed by an information processing apparatus, causes the information processing apparatus to:
instruct the processing-liquid supply device of the substrate processing system according to claim 11 to supply the processing liquid onto the substrate after the dry etching or ashing of the substrate; and
instruct the removing-liquid supply device to supply the removing liquid onto the film formed on the substrate when the processing liquid solidifies or cures on the substrate through vaporization of the volatile component in the processing liquid.
